(19) United States
(12) Patent Application Publication
(10) Pub. No.: US 2010/0212724 A1
(43) Pub. Date: Aug. 26, 2010

(54) Hollow light-collecting device

(75) Inventor: Chih-Hung Wu, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL - INSTITUTE OF NUCLEAR ENERGY RESEARCH, Taoyuan (TW)

(21) Appl. No.: 11/980,746

(22) Filed: Oct. 31, 2007

(51) Int. Cl. H01L 31/02; G02B 5/10; G02B 17/08; G01D 5/30

(52) U.S. Cl. 136/252; 359/869; 359/728; 250/216

(57) ABSTRACT

A light-collecting device has a hollow at center. Three layers are sequentially pasted on and around the hollow. The device collects light efficiently with different materials of the layers. And the device has a long life of use, is environmentally friendly and is easily mass-produced.

### FIELD OF THE INVENTION

The present invention relates to collecting light; more particularly, relates to obtaining a light-collecting device with a good light-collecting efficiency, an easy mass-production, a low cost, a long life of use and an environmentally friendly effect.

### DESCRIPTION OF THE RELATED ARTS

A conventional light-collecting device includes a block of metal with a high reflectivity. On using the device, a lens is provided on a side of the light-collecting device at a proper distance while a solar cell or a photo-sensor is provided on another side of the light-collecting device at another proper distance. Light comes from a light source and reaches the lens. The lens converges the light. The light-collecting device further converges, collects and transfers the light to the solar cell or photo-sensor. Hence, the performance of the solar cell or photo-sensor is enhanced.

Although the conventional light-collecting device is able to collect the light to enhance the performance of the solar cell or photo-sensor, the conventional light-collecting device must include a block of metal with a high reflectivity to enhance the reflection of the light. To further enhance the reflection of the light, a film with a high reflectivity is provided on the block. The film can be provided on the block by coating. Alternatively, a plate is cut into a proper shape, the film is provided on the plate by coating, and the plate coated with the film is attached to the block by gluing. The process of coating and the process of gluing are complicated and expensive. Hence, the prior arts do not fulfill all users' requests on actual use.

### SUMMARY OF THE INVENTION

The main purpose of the present invention is to obtain a light-collecting device with a good light-collecting efficiency, an easy mass-production, a low cost, a long life of use, and an environmentally friendly effect.

To achieve the above purpose, the present invention is a hollow light-collecting device, comprising a core hollow; a first layer located on and around the core hollow; a second layer located on and around the first layer; and a third layer located on and around the second layer, where the first layer is made of a light-weight transparent material; the second layer is made of a high-reflection metal adhesive material; and the third layer is made of a light-weight transparent material or a high-reflection metal adhesive material. Accordingly, a novel hollow light-collecting device is obtained.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is the perspective view showing the first preferred embodiment according to the present invention;

FIG. 2 is the sectional view showing the first preferred embodiment;

FIG. 3 is the view showing the state of use of the first preferred embodiment; and

FIG. 4 is the sectional view showing the second preferred embodiment.

### DESCRIPTIONS OF THE PREFERRED EMBODIMENTS

The following descriptions of the preferred embodiments are provided to understand the features and the structures of the present invention.

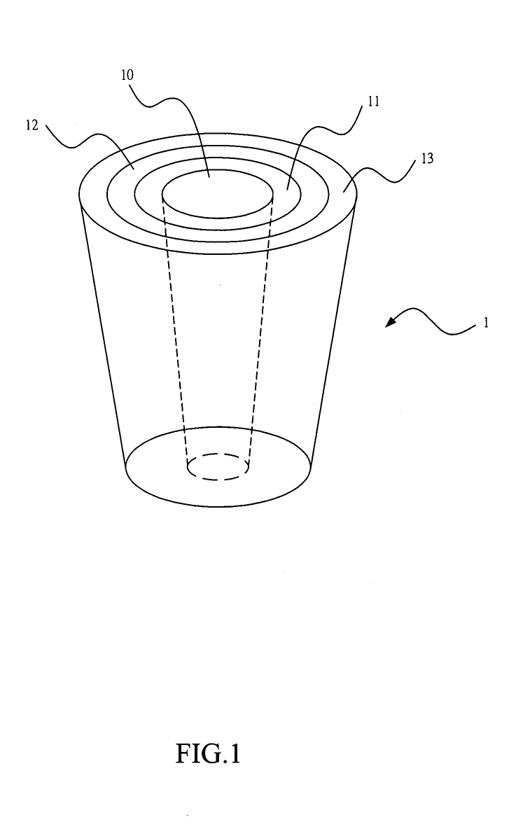

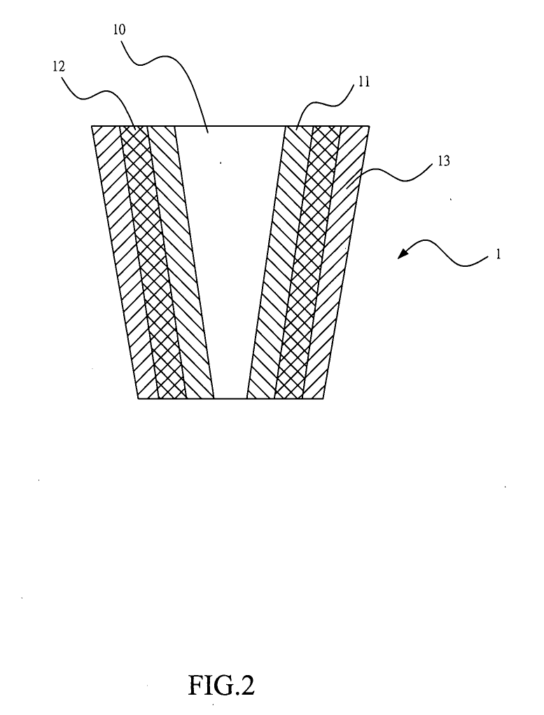

Please refer to FIG. 1 and FIG. 2, which are a perspective and a sectional views showing the first preferred embodiment according to the present invention. As shown in the figures, the present invention 1 is a hollow light-collecting device, comprising a core hollow 10, a first layer 11, a second layer 12 and a third layer 13, where the present invention 1 collects light efficiently, is easily mass-produced at a low cost, is environmentally friendly, and has a long life of use.

The core hollow 10 is located at center of the present invention 1 and is made in a form of a frustum, such as a circular frustum or a polygonal frustum.

The first layer 11 is located on and around the core hollow 10 and is made of a light-weight transparent material, such as polymethylmethacrylate (PMMA), acrylic, glass, plastic and quartz.

The second layer 12 is located on and around the first layer 11 and is made of a high-reflection metal adhesive material, such as silver glue.

The third layer 13 is located on and around the second layer 12 and is made of a light-weight transparent material, such as polymethylmethacrylate (PMMA), acrylic, glass, plastic and quartz.

Thus, a novel hollow light-collecting device is provided.

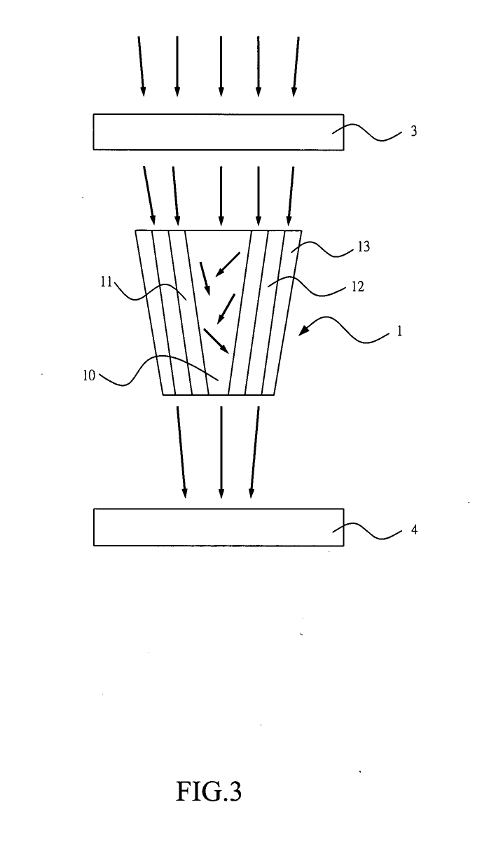

Please refer to FIG. 3, which is a view showing a state of use of the first preferred embodiment. As shown in the figure, on using the present invention, a lens 3 is provided on a side of the present invention 1 at a proper distance while a light-receiving element 4 is disposed on another side of the present invention 1 at another proper distance. The light-receiving element 4 is a solar cell or a photo sensor. Light comes from a light source and reaches the lens unit 3. Some of the light perpendicularly penetrates through the lens unit 3; and the other of the light slantingly penetrates through the lens unit 3. Because of the properties of the first, the second and the third layers 11,12,13, the present invention 1 refracts the light to the light-receiving element 4. The light is thus concentrated effectively, and the performance of the light-receiving element 4 is enhanced considerably.

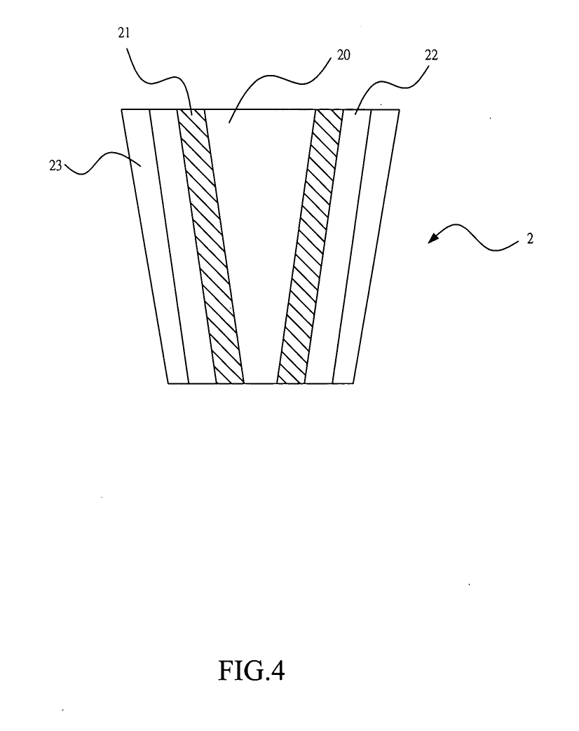

Please refer to FIG. 4, which is a sectional view showing a second preferred embodiment. As shown in the figure, the present invention 2 is a hollow light-collecting device, comprising a core hollow 20; a first layer 21 located on and around the core hollow 20; a second layer 21 located on and around the first layer 21; and a third layer 23 located on and around the second layer 22. Therein, the first layer 21 is made of a light-weight transparent material, such as PMMA, acrylic, glass, plastic or quartz; the second layer 22 is made of a high-reflection metal adhesive material, such as silver paste; and, the third layer 23 is made of a high-reflection metal adhesive material, such as silver paste. With the above structure, the present invention 2 collects light efficiently, is easily mass-produced at a low cost, is environmentally friendly, and has a long life of use.

To sum up, the present invention is a hollow light-collecting device, which collects light efficiently, is easily mass-produced at a low cost, is environmentally friendly, and has a long life of use.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A hollow light-collecting device comprising:
a core hollow being hollow and being made in a form of a frustum;
a first layer being provided on said core hollow and around said core hollow;
a second layer being provided on said first layer and around said first layer; and
a third layer being provided on said second layer and around said second layer,
wherein said first layer is made of a light-weight transparent material;
wherein said second layer is made of a high-reflection metal adhesive material; and
wherein said third layer is made of a light-weight transparent material.

2. The device according to claim 1,
wherein said light-weight transparent material is polymethylmethacrylate (PMMA).

3. The device according to claim 1,
wherein said light-weight transparent material is acrylic.

4. The device according to claim 1,
wherein said light-weight transparent material is glass.

5. The device according to claim 1,
wherein said light-weight transparent material is plastic.

6. The device according to claim 1,
wherein said light-weight transparent material is quartz.

7. The device according to claim 1,
wherein said high-reflection metal adhesive material is silver paste.

8. The device according to claim 1,
wherein said third layer is made of a high-reflection metal adhesive material.

9. The device according to claim 8,
wherein said high-reflection metal adhesive material is silver paste.

10. The device according to claim 1,
wherein an apparatus using said hollow light-collecting device comprises
said hollow light-collecting device;
a lens, said lens located at an end of said hollow light-collecting device; and
a light-receiving element located at another end of said hollow light-collecting device

11. The device according to claim 10,
wherein said light-receiving element is selected from a group consisting of a solar cell and a photo sensor.
